(19) United States
(12) Patent Application Publication
(10) Pub. No.: US 2025/0006748 A1
(43) Pub. Date: Jan. 2, 2025

(54) Light Sensor Structure and Packaging Method thereof

(71) Applicant: SENSORTEK TECHNOLOGY CORP., Hsinchu County (TW)

(72) Inventors: Ping-Jung Chiang, Hsinchu County (TW); Liang-Kuang Wei, Hsinchu County (TW); Yi-Feng Chang, Hsinchu County (TW)

(21) Appl. No.: 18/597,970

(22) Filed: Mar. 7, 2024

Related U.S. Application Data
(60) Provisional application No. 63/450,393, filed on Mar. 7, 2023.

(51) Int. Cl. H01L 27/144; H01L 25/16; H01L 33/00; H01L 33/62

(52) U.S. Cl. CPC H01L 27/1446; H01L 25/167; H01L 33/0093; H01L 33/62; H01L 2933/0066

(57) ABSTRACT

A light sensor structure and a packaging method thereof are disclosed. The light sensor structure comprises a light emitting element, a light sensing element, an opaque molding substance, an insulation layer and a connection layer. The opaque molding substance encloses the light emitting element and the light sensing element, and the opaque molding substance is provided with a via. The insulation layer is disposed on the bottom surface of the light emitting element, and the insulation layer is provided with a number of connection pads on a side away from the light emitting element and the light sensing element. The connection pads are electrically connected to the contacts on the bottom surface of the light emitting element through the connection layer, and the connection pads are electrically connected to the contacts on the light sensing surface of the light sensing element through the connection layer and the via.

### FIELD OF THE INVENTION

The present invention is related to a light sensor structure and packaging method thereof, in particular to a method for packaging a light sensor structure comprising a light emitting element and a light sensing element.

### BACKGROUND OF THE INVENTION

Light sensors, such as proximity sensors (PS), ambient light sensors and so on, are widely applied in portable mobile devices, such as mobile phones, and in other consumer electronic devices. Proximity sensors may be used to detect the distance between the user's face or other objects and the electronic device; ambient light sensors may be applied in electronic devices to sense the intensity of ambient light. Both proximity sensors and ambient light sensors require light sensing elements, and proximity sensors generally require light emitting elements (such as infrared emitters or laser light emitters).

In the prior art, to package a light sensor structure comprising a light emitting element and a light sensing element, the light emitting element and the light sensing element are usually arranged jointly on a semiconductor substrate after wire bonding has been completed. These light emitting elements and light sensing elements are sealed in a transparent molding substance made by molding with these photoelectric devices, so as to protect the light emitting elements and light sensing elements without affecting the penetration of light. Afterward, additional optical structures or light-shielding covers will be further integrated into the light sensor structure to meet actual product requirements.

To comply with design trends, such as full-screen consumer electronic devices, miniaturization of light sensor structures is a top priority for product development. Manufacturers are trying every means to reduce the overall volume of light sensor structures. However, in the existing technology, the wire-bonded light emitting elements and the light sensing elements already occupy a certain volume, and the required transparent molding substance also demands some volume. This leads to the possible degree of miniaturization of the light sensor structures being limited by using packaging of the existing technology.

Based on the above deficiencies, it is necessary to improve the structure and manufacturing process of light sensors to achieve overall miniaturization, and better meet the needs of practical applications.

### SUMMARY OF THE INVENTION

An objective of the present invention is to provide a light sensor structure and its packaging method. By improving the structure and manufacturing process of the light sensor, the overall size of the light sensor structure packaged according to the embodiment of the present invention may be significantly reduced, thereby achieving overall miniaturization. Furthermore, no transparent molding substance is required, which may simplify the manufacturing process while maintaining good reliability.

The present invention discloses a light sensor structure, which comprises a light emitting element, a light sensing element, an opaque molding substance, an insulation layer, and a connection circuit. The light emitting element includes a light emitting surface and a bottom surface located on two sides of the light emitting element along a first direction. The light sensing element includes a light sensing surface. The opaque molding substance covers the light emitting element and the light sensing element. In addition, the opaque molding substance includes a via for forming an electrical connection structure. The insulation layer is disposed on the bottom surface of the light emitting element. Besides, the insulation layer includes a plurality of connection pads on a side of the insulation layer away from the light emitting element and the light sensing element along the first direction. The connection pads are connected to the contacts on the bottom surface of the light emitting element through the connection circuit and the electrical connection structure in the via. At least one of the light emitting element and the light sensing element is a bare die to form a bare die interface between the opaque molding substance and the light emitting element or the light sensing element.

The present invention discloses a method for packaging a light sensor structure comprising a light emitting element and a light sensing element. The light emitting element includes a light emitting surface and a bottom surface located on two sides of the light emitting element along a first direction. The light sensing element includes a light sensing surface. The packaging method comprises steps of: fixing the light emitting surface of the light emitting element and the light sensing surface of the light sensing element on a substrate along the first direction; covering the light emitting element and the light sensing element with an opaque molding substance; removing a portion of the opaque molding substance along the first direction for exposing the bottom surface of the light emitting element; removing the substrate and opening a via in the opaque molding substance, the via penetrating two sides of the opaque molding substance along the first direction, and forming an electrical connection structure in the via; and forming a connection circuit and an insulation layer, and forming a plurality of connection pads on a side of the insulation layer away from the light emitting element and the light sensing element along the first direction. The connection pads are electrically connected to the contacts on the bottom surface of the light emitting element through the connection circuit. Besides, the connection pads are electrically connected to the contacts on the light sensing surface of the light sensing element through the connection circuit and the electrical connection structure in the via.

The present invention further discloses a light sensor structure, which is packaged using the method for packaging light sensor structure described above.

### BRIEF DESCRIPTION OF DRAWINGS

FIG. 1A shows the step of fixing the light emitting element and the light sensing element;

FIG. 1B shows the step of forming the opaque molding substance;

FIG. 1C shows the step of removing a portion of the opaque molding substance;

FIG. 1D shows the step of removing the substrate;

FIG. 1E shows the step of forming the via;

FIG. 1F shows the step of forming the connection circuit, the insulation layer, and the connection pads;

FIG. 1G shows the step of forming the cover;

FIG. 2 shows a top view of the light sensor structure; and

FIG. 3 shows a bottom view of the light sensor structure.

### DETAILED DESCRIPTION OF THE INVENTION

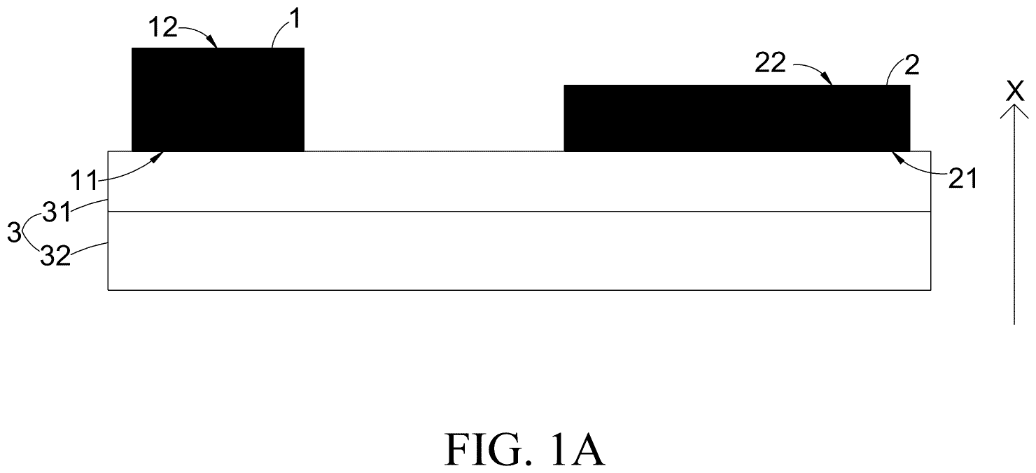

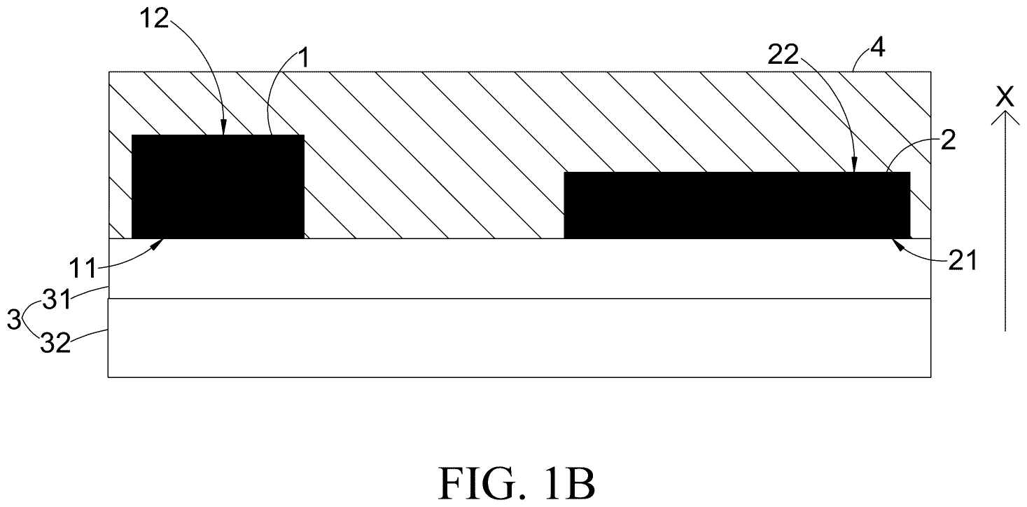

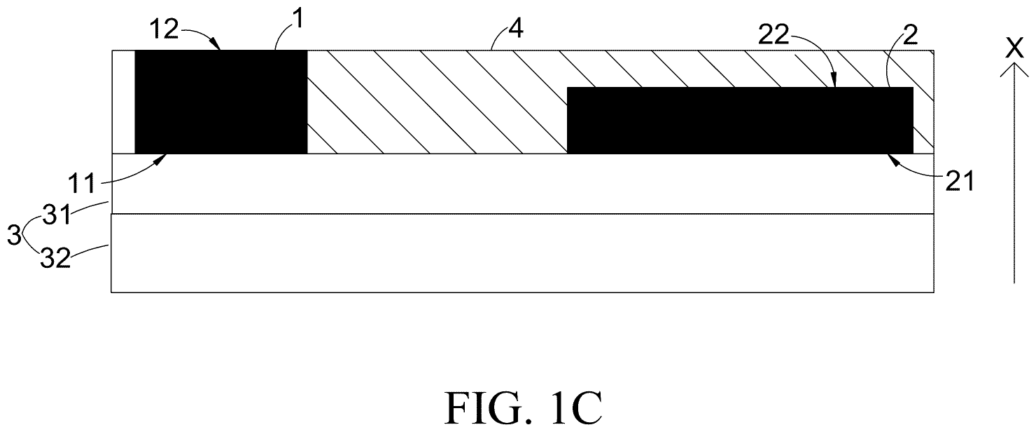

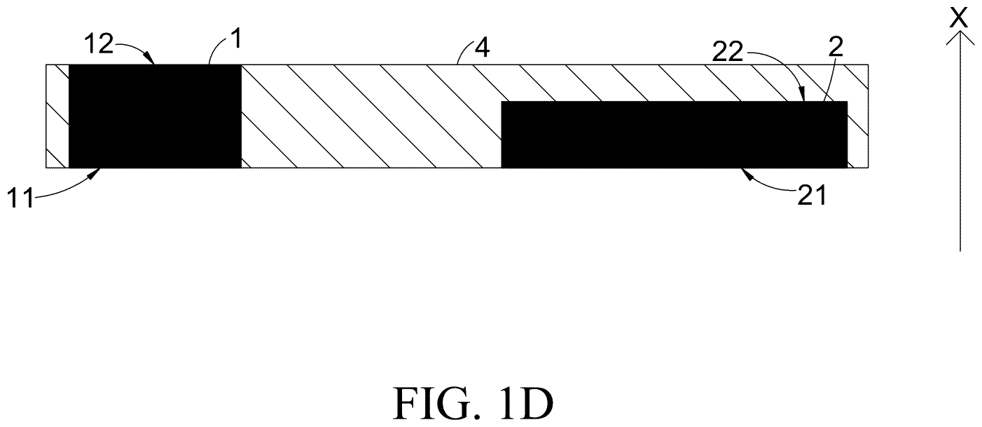

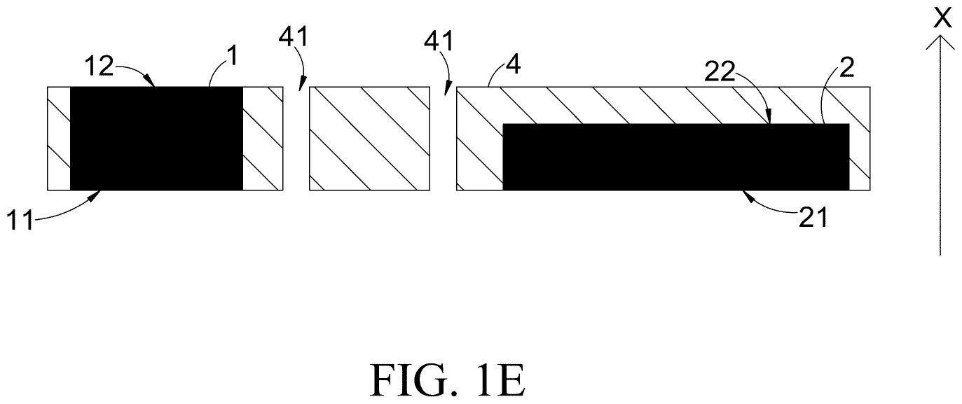

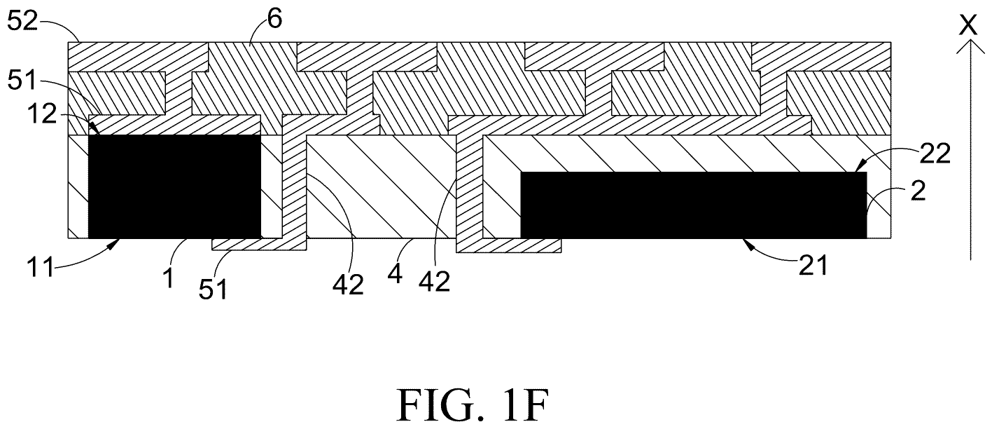

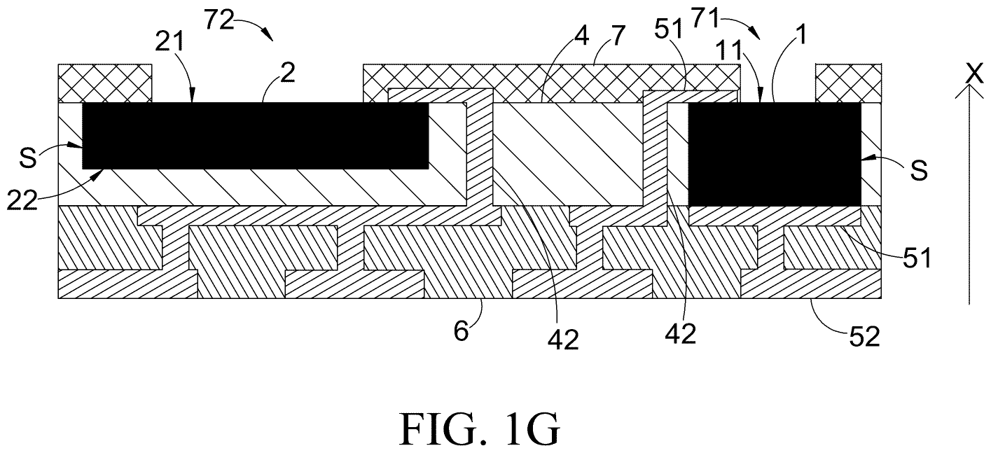

Please refer to FIG. 1A to 1G, which show the method for packaging a light sensor structure according to an embodiment of the present invention. First, prepare one or more light emitting element and one or more light sensing element. For convenience, according to the present embodiment, one light emitting element 1 and one or more light sensing element 2 are adopted as an example for illustration. At least one of the light emitting element 1 and the light sensing element 2 is a bare die. Preferably, all of them are bare dies. A bare die is a device after die sawing and without undergoing the packaging procedures such as wiring and bonding. The light emitting element 1 may be a light emitting diode (LED) or a laser diode such as EEL or VCSEL. In addition, the light emitting element 1 includes a light emitting surface 11 and a bottom surface 12 on the side of the light emitting element 1 away from the light emitting surface 11 along a first direction X. Taking a vertical-cavity surface-emitting laser (VCSEL) as the light emitting element 1 for example. The contacts of the light emitting element 1 are normally located on the light emitting surface 11 and the bottom surface 12. Besides, flip-chip technology may be used to fabricate VCSEL devices.

The light sensing element 2 may be integrated into an application-specific integrated circuit (ASIC) so that the light sensing element 2 may include a photodiode and the operational circuit, such as the analog-to-digital converter or other operational circuits for the proximity sensor and/or the ambient light sensor, concurrently. Alternatively, if there are other design considerations, the light sensing element 2 may include only a photodiode. In general, a photodiode is formed by fabricating a PN junction or a PIN junction on a light sensing surface 21. The contacts of the photodiode or the operational circuit described above are normally disposed on the light sensing surface 21 as well. Accordingly, the side of the light sensing element 2 away from the light sensing surface 21 along the first direction X is a back surface 22. The back surface 22 is usually the back of the chip (the back side of a wafer) without any contact.

As shown in FIG. 1A, fix the light emitting surface 11 of the light emitting element 1 and the light sensing surface 21 of the light sensing element 2 on a substrate 3 along the first direction X. The substrate 3 may be a tape or other removable materials. According to the present embodiment, the substrate 3 includes a thermal release layer 31 and a carrier layer 32. The thermal release layer 31 may be formed by a thermal release tape and disposed on the carrier layer 32 along the first direction X. In other words, the light emitting surface 11 of the light emitting element 1 and the light sensing surface 21 of the light sensing element 2 are fixed on the thermal release layer 31.

Next, as shown in FIG. 1B, cover the light emitting element 1 and the light sensing element 2 with an opaque molding substance 4. According to the present embodiment, the opaque molding substance 4 is, for example, epoxy resin, silicone, a mixture of resin and silicone, and acrylic glue. In addition, the opaque molding substance 4 may be black epoxy resin, which itself is an opaque material. Alternatively, the opaque molding substance 4 may be formed by adding additives such as dyes, carbon black, silicon dioxide, or titanium dioxide. Thereby, the opaque molding substance 4 may shield light. After solidification, it may protect the light emitting element 1 and the light sensing element 2.

It should be noted that the “opacity” described in the specification and the claims of the present invention does not necessarily block all light. Once a material can block the light within the wavelength range receivable by the light sensing element 2, it is regarded as opaque.

According to the foregoing description, the contacts of the light emitting element 1 may be distributed on the bottom surface 12; and there is normally no contact on the back surface 22 of the light sensing element 2. Accordingly, as shown in FIG. 1C, remove a portion of the opaque molding substance 4 along the first direction X by polishing or etching to expose the bottom surface 12 of the light emitting element 1.

Note that if the polishing method is adopted to remove the opaque molding substance 4 and the height of the light emitting element 1 in the first direction X is greater than the height of the light sensing element 2, the step shown in FIG. 1C will not affect the light sensing element 2. Contrarily, if a different type of the light emitting element 1 with a height in the first direction X smaller than that of the light sensing element 2 is selected, when the bottom surface 12 of the light emitting element 1 is exposed by polishing, the light sensing element 2 might be thinned as well. To avoid direct loss of the light signal from the back surface 22 of the light sensing element 2, The US Patent publication No. 20220128400A1 proposed by the present applicant may be referred to for fabricating an additional reflective layer on the back surface 22. Since the related technology is not within the scope of the present invention, the details will not be described.

As shown in FIG. 1D, remove the substrate 3. To elaborate, according to the present embodiment, the thermal release layer 31 of the substrate 3 may be formed by thermal release tape. Thereby, the substrate 3 may be removed with ease by heating. On the contrary, if the substrate 3 is made by other materials, a removing agent or other means should be adopted to remove the substrate 3.

Furthermore, as shown in FIG. 1E, open one or more vias 41 in the opaque molding substance 4. The via 41 penetrates two sides of the opaque molding substance 4 along the first direction X, and an electrical connection structure 42 is formed in the via 41. For example, the electrical connection structure 42 may be a through mold via (TMV) formed by laser drilling. Of course, a traditional via may be adopted to manufacture the electrical connection structure 42.

Alternatively, the order of the steps in FIG. 1D and FIG. 1E may be switched. For example, open the via penetrating the substrate 3 and the opaque molding substance 4 before removing the substrate 3. Then one or more vias 41 may be formed in the opaque molding substance 4 as well.

According to the present embodiment, one or more of the light emitting element 1 and the light sensing element 2 is a bare die. Preferably, all of them are bare dies. Thereby, as shown in FIG. 1F, a connection circuit 51 and connection pads 52 should be fabricated to connect the contacts of the light emitting element 1 and the light sensing element 2. To elaborate, the light sensor structure will include a plurality of connection pads 52 as the input/output for electronic devices. These connection pads 52 will be connected to the contacts of the light emitting element 1 and the light sensing element 2, respectively. The contacts of the light sensing element 2 are normally disposed on the light sensing surface 21. However, the connection pads are located on the different side of the light sensing surface along the first direction X. Accordingly, the connection circuit 51 fabricated using a redistribution layer (RDL) may be used to electrically connect to the electrical connection structure 42 in the via 41, thus electrically connecting with the connection pads 52 and the contacts of the light sensing surface 21 at two sides of the connection circuit 51 along the first direction X. While the connection circuit 51 may be fabricated by using the redistribution layer, an accompanying insulation layer 6 made of a polyimide dielectric layer (PI) is normally adopted to form one layer or multiple layers of wiring structure. In addition, the insulation layer 6 may fix the connection pads 52 as well. Optionally, the above connection circuit 51 and the insulation layer 6 may be fabricated using other processes.

On the other hand, the connection circuit 51 will be electrically connected to the light emitting element 1. When the contacts of the light emitting element 1 are located only on the bottom surface 12, the connection pads 52 may be electrically connected to the contacts on the bottom surface 12 easily. Under this circumstance, the number of vias 41 in the opaque molding substance 4 may be one. Nonetheless, as described above, according to the present embodiment, the light emitting element 1 is a VCSEL device. The contacts of the light emitting element 1 are normally located on the light emitting surface 11 and the bottom surface 12. The connection pads 52 are located on the different side from the light emitting surface 11 along the first direction X. Thereby, it is required to use the connection circuit 51 to connect to the electrical connection structure 42 in the other via 41 for electrically connecting the connection pads 52 to the contacts of the light emitting element 1 on two sides along the first direction X, respectively.

In practice, the light sensor structure shown in FIG. 1F may be regarded as a finished product and may be applied as a proximity sensor or an ambient light sensor. Nonetheless, in the applications of proximity sensors, to avoid influence by crosstalk signals, a cover will be added to block the light emitted from the light emitting element 1 to the light sensing element 2 directly instead of reflecting from external objects. Accordingly, as shown in FIG. 1G, a cover 7 is additionally disposed on the light emitting surface 11 of the light emitting element 1 and the light sensing surface 21 of the light sensing element 2. The cover 7 includes a first opening 71 and a second opening 72. The first opening 71 communicates with the light emitting surface 11; the second opening 72 communicates with the light sensing surface 21 for allowing light passage. Thereby, the cover 7 and the opaque molding substance 4 together may limit the transmission path of light and hence lower the crosstalk component. Furthermore, the size of the second opening 72 may be used to limit the light-receiving angle of an ambient light sensor as well.

It is noteworthy that there are many forms and binding methods for the cover 7 and it's not possible to list all of them. Nonetheless, as described above, a polyimide dielectric layer may be used to fabricate the insulation layer 6. Polyimide is a type of polymer with repeating imide units, which may be transparent or opaque depending on its type. If the insulation layer 6 is opaque, in the method for packaging light sensor structure according to an embodiment of the present invention, the same polyimide dielectric layer may be used to manufacture the cover 7, thus reducing the difficulty and complexity of packaging to the greatest extent possible. The only thing to be noted is that, in FIG. 1G, if the light sensor structure is not flipped before forming the connection circuit 51, the connection pads 52, and the insulation layer 6, the light emitting surface 11 of the light emitting element 1 and the light sensing surface 21 of the light sensing element 2 will maintain facing down along the first direction X. Consequently, before forming the cover 7 in FIG. 1F, the light sensor structure should be flipped to make the light emitting surface 11 of the light emitting element 1 and the light sensing surface 21 of the light sensing element 2 face up along the first direction X to facilitate processing.

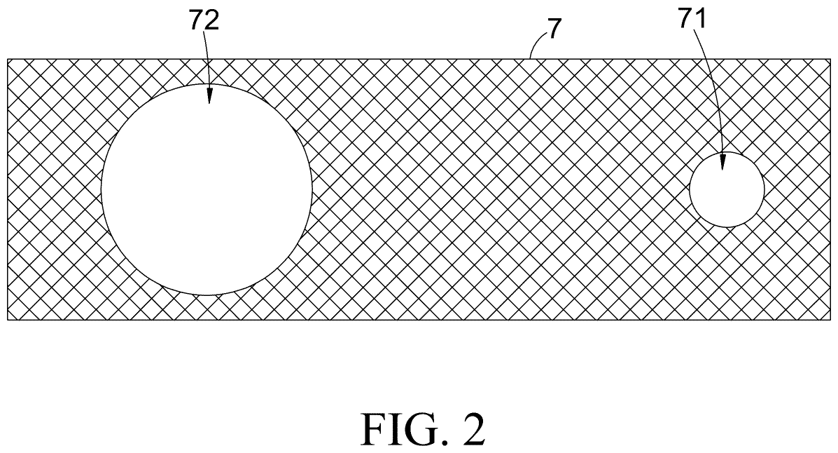

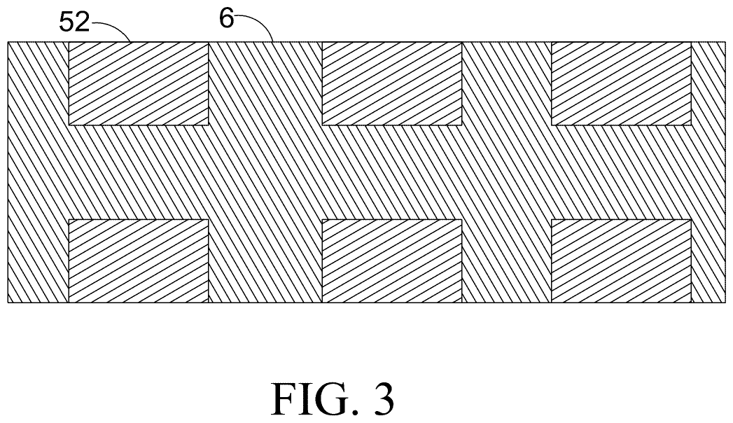

The light sensor structure shown in FIG. 1G may be regarded as a finished product and may be applied as a proximity sensor or an ambient light sensor. In addition, FIG. 2 shows a top view of the light sensor structure. It may be seen that the top view of the light sensor structure includes the cover 7, as well as the second opening 72 and the first opening 71 for receiving and emitting light. FIG. 3 shows a bottom view of the light sensor structure. It may be seen that the bottom view of the light sensor structure includes the connection pads 52 used for contacting the input/output of an electronic device. Accordingly, the light sensor structure packaged according to the embodiment of the present invention may completely replace the one packaged according to the prior art.

The major difference between the light sensor structure packaged according to the embodiment of the present invention and the one according to the prior art is that, according to the present embodiment, one or more of the light emitting element 1 and the light sensing element 2 is a bare die. Preferably, all of them are bare dies. Accordingly, there exists one or more bare die interfaces S in the light sensor structure according to the present invention. To elaborate, please continue to refer to FIG. 1F and FIG. 1G. Given that the light emitting element 1 and the light sensing element 2 are two bare dies, the interface between the light emitting element 1 and the opaque molding substance 4 is a bare die interface S; the interface between the light sensing element 2 and the opaque molding substance 4 is another bare die interface S. This means that, according to the embodiment of the present invention, the bare dies of the light emitting element 1 and the light sensing element 2 may contact the opaque molding substance 4 directly. In comparison, in the prior art, the light emitting element and the light sensing element that have been wire bonded are used for packaging. Therefore, at least a space for wiring and gluing will be formed by the distance between the external packaging structure and the bare dies of the light emitting element and the light sensing element. Not to mention that the light emitting element and the light sensing element will be sealed in the transparent molding substance according to the prior art, where an additional space for the transparent molding substance will be further formed by the distance between the bare dies of the light emitting element and the light sensing element and the external packaging structure.

Moreover, according to the present embodiment, both the light emitting element 1 and the light sensing element 2 may be bare dies. In the packaging process, the light emitting surface 11 of the light emitting element 1 and the light sensing surface 21 of the light sensing element 2 will be fixed facing down on the substrate 3. The subsequent opaque molding substance 4 will not affect the light emitting surface 11 of the light emitting element 1 and the light sensing surface 21 of the light sensing element 2, thus ensuring excellent optical and electrical characteristics of the packaged light sensor structure.

Accordingly, the overall size of the light sensor structure after packaging according to the embodiment of the present invention may be significantly reduced. In an implementation example, after the light sensor structure that originally required about 5.5*2.4*1 mm is packaged using the embodiment of the present invention, its size may be reduced to about 4*2*0.2 mm, achieving the purpose of miniaturization. Furthermore, embodiments of the present invention do not need to use transparent molding substances to protect the light emitting elements and the light sensing elements, which may effectively simplify the process steps and reduce packaging costs. In addition, the light sensor structure packaged using embodiments of the present invention has good reliability, and the reliability of wafer level chip scale package (WLCSP) may reach Level 1.

To sum up, the present invention provides a light sensor structure and the packaging method thereof. By the improved structure and process, the overall size of the light sensor structure packaged according to the embodiment of the present invention is shrunk significantly to achieve the purpose of overall miniaturization. In addition, since no transparent molding substance is required, the process may be simplified and the reliability may be improved.

The foregoing description is only of embodiments of the present invention. Those equivalent changes or modifications made according to the claims of the present invention are included in the scope of the present invention.

1. A light sensor structure, comprising:
a light emitting element, comprising a light emitting surface and a bottom surface located on two sides of the light emitting element along a first direction;
a light sensing element, comprising a light sensing surface;
an opaque molding substance, covering the light emitting element and the light sensing element, and including a via, an electrical connection structure formed within the via;
an insulation layer, disposed on the bottom surface of the light emitting element, and comprising a plurality of connection pads disposed at a side of the insulation layer away from the light emitting element and the light sensing element along the first direction; and
a connection circuit, the connection pads connected to contacts on the bottom surface of the light emitting element through the connection circuit, the connection pads connected to contacts on the light sensing surface of the light sensing element through the electrical connection structure in the via and the connection circuit;
wherein one of the light emitting element and the light sensing element is a bare die, and a bare die interface is formed between the opaque molding substance and the light emitting element or the light sensing element.

2. The light sensor structure of claim 1, wherein the light emitting element and the light sensing element are bare dies, respectively; and bare die interfaces of them are formed between the opaque molding substance and the light emitting element and between the opaque molding substance and the light sensing element, respectively.

3. The light sensor structure of claim 1, wherein the opaque molding substance further includes an another via, an another electrical connection structure is formed in the another via, and the connection pads are electrically connected to the contacts on the light emitting surface of the light emitting element through the another electrical connection structure in the another via and the connection circuit.

4. The light sensor structure of claim 1, further comprising a cover disposed on the light emitting surface of the light emitting element and the light sensing surface of the light sensing element along the first direction, wherein the cover includes a first opening and a second opening, the first opening communicates with the light emitting surface; and the second opening communicates with the light sensing surface.

5. The light sensor structure of claim 1, wherein the connection circuit is formed by a redistribution layer, and the insulation layer is formed by a polyimide dielectric layer.

6. The light sensor structure of claim 1, wherein the light emitting element is a vertical-resonant-cavity surface-emitting laser device.

7. The light sensor structure of claim 1, wherein the light sensing element includes a back surface;
the light sensing surface and the back surface are located on two sides of the light sensing element along the first direction; and the back surface includes no contact.

8. A method for packaging a light sensor structure, for packaging a light sensor structure, comprising a light emitting element and a light sensing element, the light emitting element comprising a light emitting surface and a bottom surface located on two sides of the light emitting element along a first direction, the light sensing element comprising a light sensing surface, comprising steps of:
fixing the light emitting surface of the light emitting element and the light sensing surface of the light sensing element on a substrate along the first direction;
forming an opaque molding substance covering the light emitting element and the light sensing element;
removing a portion of the opaque molding substance along the first direction to expose the bottom surface of the light emitting element;
removing the substrate and opening a via in the opaque molding substance, the via penetrating two sides of the opaque molding substance along the first direction, and forming an electrical connection structure in the via; and
forming a connection circuit and an insulation layer, and forming a plurality of connection pads on one side of the light emitting element away from the light emitting element and the light sensing element along the first direction;
wherein the connection pads are electrically connected to contacts on the bottom surface of the light emitting element through the connection circuit; and the connection pads are electrically connected to contacts on the light sensing surface of the light sensing element through the connection circuit and the electrical connection structure in the via.

9. The method for packaging light sensor structure of claim 8, wherein at least one of the light emitting element and the light sensing element is a bare die.

10. The method for packaging light sensor structure of claim 8, wherein the light emitting element and the light sensing element are bare dies, respectively.

11. The method for packaging light sensor structure of claim 8, wherein the opaque molding substance includes another via formed thereon to form another electrical connection structure;
the connection pads are electrically connected to the contacts on the light emitting surface of the light emitting element through the another electrical connection structure in the another via and the connection circuit.

12. The method for packaging light sensor structure of claim 11, wherein the via is formed by laser drilling; and the electrical connection structure is a through mold via.

13. The method for packaging light sensor structure of claim 8, wherein the connection circuit is formed by a redistribution layer; and the insulation layer is formed by a polyimide dielectric layer.

14. The method for packaging light sensor structure of claim 8, and further comprising a step of disposing a cover on the light emitting surface of the light emitting element and the light sensing surface of the light sensing element along the first direction, wherein the cover includes a first opening and a second opening; the first opening communicates with the light emitting surface;
and the second opening communicates with the light sensing surface.

15. The method for packaging light sensor structure of claim 14, wherein the connection circuit is formed by a redistribution layer, and the insulation layer and the cover are formed by a polyimide dielectric layer.

16. The method for packaging light sensor structure of claim 8, wherein the one portion of the opaque molding substance is removed by the polishing method.

17. The method for packaging light sensor structure of claim 8, wherein the substrate includes a thermal release layer and a carrier layer, the thermal release layer is disposed on the carrier layer along the first direction, and the light emitting surface of the light emitting element and the light sensing surface of the light sensing element are fixed on the thermal release layer.

18. A light sensor structure, which is packaged using the method for packaging light sensor structure of claim 8.
